(19) United States
(12) Patent Application Publication
(10) Pub. No.: US 2024/0145472 A1
(43) Pub. Date: May 2, 2024

(54) SEMICONDUCTOR STRUCTURE WITH DIELECTRIC PILLARS

(71) Applicant: International Business Machines Corporation, Armonk, NY (US)

(72) Inventors: Kangguo Cheng, Schenectady, NY (US); Julien Frougier, Albany, NY (US); Ruilong Xie, Niskayuna, NY (US); Chanro Park, Clifton Park, NY (US); Min Gyu Sung, Latham, NY (US)

(21) Appl. No.: 17/977,281

(22) Filed: Oct. 31, 2022

(51) Int. Cl. H01L 27/092; H01L 21/8238; H01L 29/06; H01L 29/423; H01L 29/66; H01L 29/775

(52) U.S. Cl. CPC H01L 27/092; H01L 21/823807; H01L 21/823878; H01L 29/0673; H01L 29/42392; H01L 29/66439; H01L 29/775

(57) ABSTRACT

A semiconductor structure includes a first transistor device, a second transistor device, and a dielectric pillar structure disposed between the first transistor device and the second transistor device. The dielectric pillar structure includes a first dielectric pillar adjacent the first transistor device and a second dielectric pillar adjacent the second transistor device.

### BACKGROUND

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor FETs (MOSFETs). Complementary MOS (CMOS) devices are widely used, where both n-type and p-type transistors (nFET and pFET) are used to form logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

### SUMMARY

Illustrative embodiments of the present application include techniques for use in semiconductor manufacture. In one illustrative embodiment, a semiconductor structure comprises a first transistor device, a second transistor device, and a dielectric pillar structure disposed between the first transistor device and the second transistor device. The dielectric pillar structure comprises a first dielectric pillar adjacent the first transistor device and a second dielectric pillar adjacent the second transistor device.

In another illustrative embodiment, a semiconductor structure comprises a first transistor device disposed on a substrate; a second transistor device disposed on the substrate and adjacent the first transistor device; and a dielectric pillar structure disposed between the first transistor device and the second transistor device. The dielectric pillar structure comprises a first dielectric pillar disposed on the first transistor device and on a portion of the substrate, a second dielectric pillar disposed on the second transistor device and on sidewalls and a bottom portion of the first dielectric pillar and an interlayer dielectric layer disposed within the second dielectric pillar.

In yet another illustrative embodiment, an integrated circuit comprises one or more semiconductor structures. At least one of the one or more semiconductor structures comprise a first transistor device, a second transistor device, and a dielectric pillar structure disposed between the first transistor device and the second transistor device. The dielectric pillar structure comprises a first dielectric pillar adjacent the first transistor device and a second dielectric pillar adjacent the second transistor device.

Other embodiments will be described in the following detailed description of embodiments, which is to be read in conjunction with the accompanying figures.

### BRIEF DESCRIPTION OF THE DRAWINGS

FIG. 1 depicts a cross sectional view illustrating a semiconductor structure for use at a first-intermediate fabrication stage, according to an illustrative embodiment.

FIG. 2 depicts a side cross-sectional view of a semiconductor structure for use at a second-intermediate fabrication stage, according to an illustrative embodiment.

FIG. 3 depicts a side cross-sectional view of a semiconductor structure for use at a third-intermediate fabrication stage, according to an illustrative embodiment.

FIG. 4 depicts a side cross-sectional view of a semiconductor structure for use at a fourth-intermediate fabrication stage, according to an illustrative embodiment.

FIG. 5 depicts a side cross-sectional view of a semiconductor structure for use at a fifth-intermediate fabrication stage, according to an illustrative embodiment.

FIG. 6 depicts a side cross-sectional view of a semiconductor structure for use at a sixth-intermediate fabrication stage, according to an illustrative embodiment.

FIG. 7 depicts a side cross-sectional view of a semiconductor structure for use at a seventh-intermediate fabrication stage, according to an illustrative embodiment.

FIG. 8 depicts a side cross-sectional view of a semiconductor structure for use at an eighth-intermediate fabrication stage, according to an illustrative embodiment.

FIG. 9 depicts a cross-sectional view of a semiconductor structure starting from FIG. 4 for use at a first-intermediate fabrication stage, according to an alternative illustrative embodiment.

FIG. 10 depicts a a cross-sectional view of a semiconductor structure for use at a second-intermediate fabrication stage, according to an alternative illustrative embodiment.

FIG. 11 depicts a side cross-sectional view of a semiconductor structure for use at a third-intermediate fabrication stage, according to an alternative illustrative embodiment.

FIG. 12 is a cross-sectional view illustrating the semiconductor structure for use at a fourth-intermediate fabrication stage, according to an alternative illustrative embodiment.

FIG. 13 is a cross-sectional view illustrating the semiconductor structure for use at a fifth-intermediate fabrication stage, according to an alternative illustrative embodiment.

FIG. 14 is a cross-sectional view illustrating the semiconductor structure for use at a sixth-intermediate fabrication stage, according to an alternative illustrative embodiment.

FIG. 15 is a cross-sectional view illustrating the semiconductor structure starting from FIG. 11 for use at a first-intermediate fabrication stage, according to another alternative illustrative embodiment.

FIG. 16 depicts a side cross-sectional view of a semiconductor structure for use at a second-intermediate fabrication stage, according to another alternative illustrative embodiment.

### DETAILED DESCRIPTION

Illustrative embodiments of the invention may be described herein in the context of illustrative methods for forming a dielectric pillar structure of two or more dielectric material used next to an nFET region and a pFET region, respectively, to independently and simultaneously improve the electrostatics of the nFET and pFET regions, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-the-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Present semiconductor processing forms a singular dielectric pillar between an nFET region and a pFET region. The singular dielectric pillar is formed from a dielectric material typically carrying a fixed charge. For example, one such dielectric material is silicon nitride (SiN) which has a positive fixed charge. However, when forming a dielectric pillar from, dielectric material carrying a positively fixed charge, the positive charges weaken the electrostatics of the nFET region.

Illustrative embodiments provide methods and structures for overcoming the foregoing drawbacks by forming a dielectric pillar structure of two or more dielectric material having oppositely fixed charged next to an nFET region and a pFET region, respectively, to independently and simultaneously improve the electrostatics of the nFET and pFET regions.

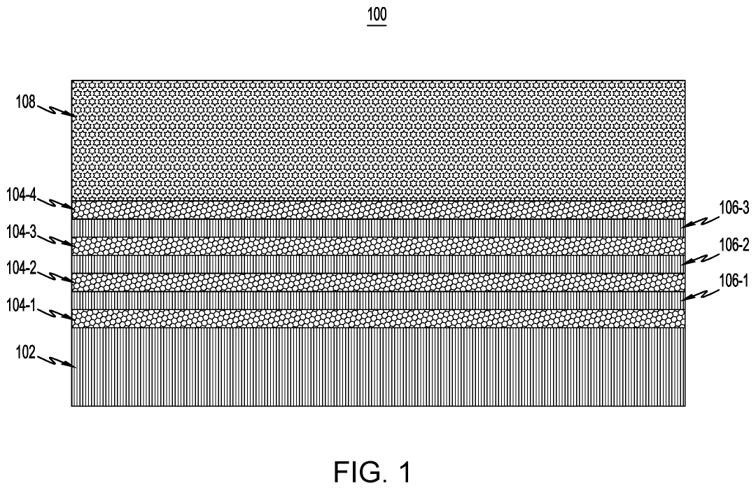

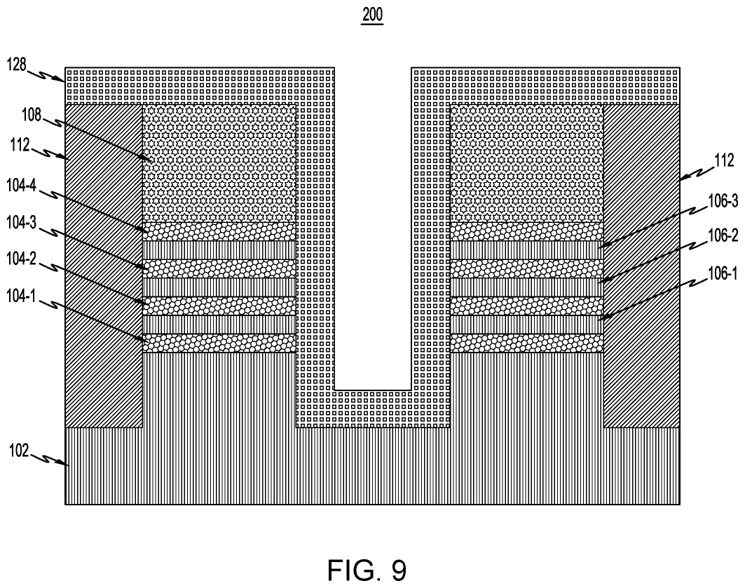

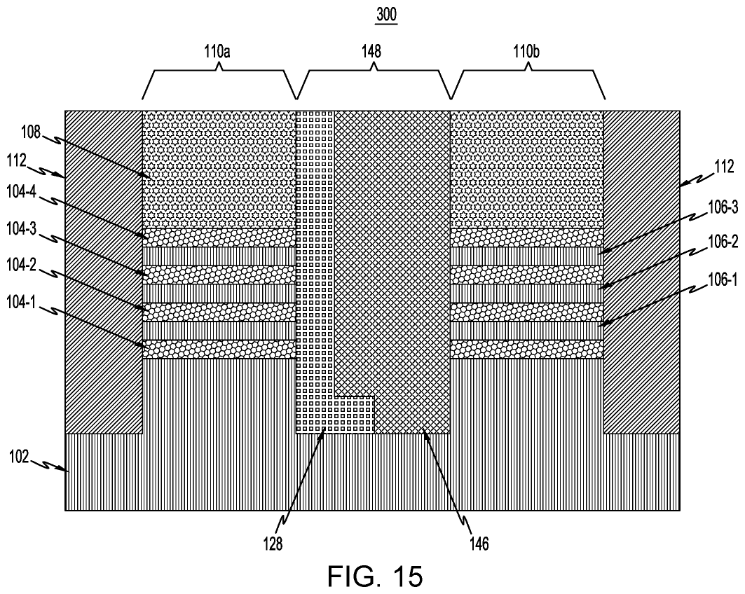

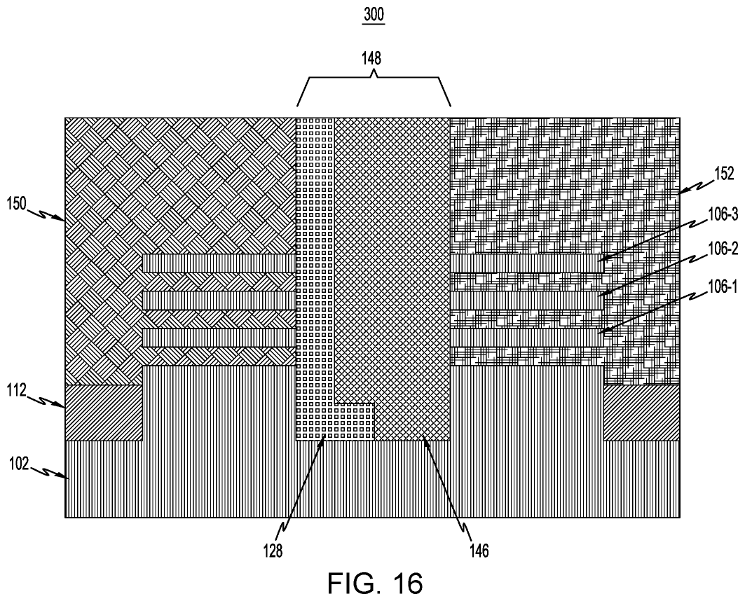

Referring now to the drawings in which like numerals represent the same of similar elements, FIGS. 1-16 illustrate various processes for fabricating semiconductor structures having an interconnect with a disconnected liner and metal cap to prevent diffusion of the metal from the metal cap into the liner. Note that the same reference numeral (100) is used to denote the semiconductor structure through the various intermediate fabrication stages illustrated in the embodiments disclosed in FIGS. 1-8, the same reference numeral (200) is used to denote the semiconductor structure through the various intermediate fabrication stages illustrated in the embodiments disclosed in FIGS. 9-14, and the same reference numeral (300) is used to denote the semiconductor structure through the various intermediate fabrication stages illustrated in the embodiments disclosed in FIGS. 15 and 16. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-16 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIGS. 1-8 in one non-limiting illustrative embodiment, FIG. 1 shows a semiconductor structure 100 having substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

Nanosheets are formed over the substrate 102, where the nanosheets include sacrificial layers 104-1, 104-2, 104-3 and 104-4 (collectively, sacrificial layers 104), and nanosheet channel layers 106-1, 106-2 and 106-3 (collectively, nanosheet channel layers 106).

The sacrificial layers 104 are illustratively formed of a sacrificial material, such that they may be etched or otherwise removed selectively. In some embodiments, the sacrificial layers 104 are formed of SiGe. For example, the sacrificial layers 104 may have a relatively higher percentage of Ge (e.g., 55% Ge) or a relatively lower percentage of Ge (e.g., 25% Ge).

The nanosheet channel layers 106 may be formed of Si or another suitable material (e.g., a material similar to that used for the substrate 102).

Although four layers each of the sacrificial layers 104 and three layers of the nanosheet channel layers 106 are shown, the number of sacrificial layers 104 and the nanosheet channel layers 106 should not be considered limiting and any number are contemplated.

Semiconductor structure 100 further has a hardmask layer 108 on the topmost layer of nanosheet channel layers 106. The material of the hardmask layer 108 may include SiN, a multi-layer of SiN and SiO₂, or another suitable material. Hardmask layer 108 can be formed by depositing the hardmask material using any conventional deposition technique such as physical vapor deposition (PVD), atomic layer deposition (ALD), chemical vapor deposition (CVD) and/or plating, followed by a planarization process such as chemical mechanical planarization (CMP) process.

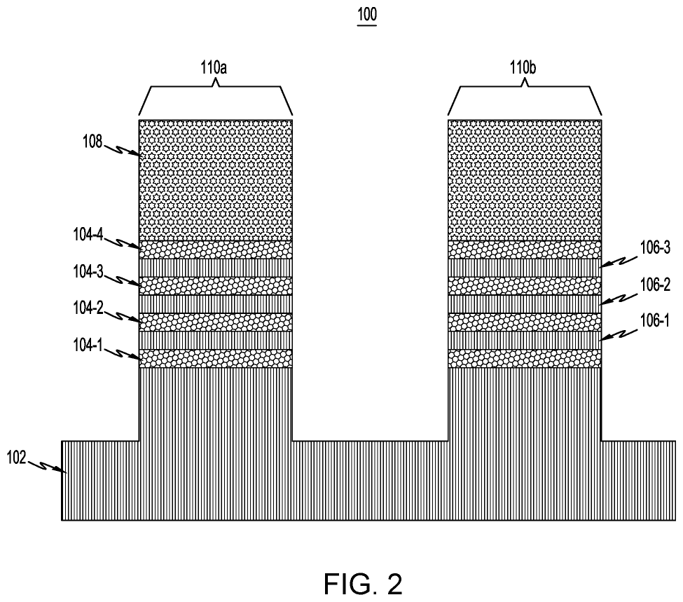

FIG. 2 shows semiconductor structure 100 at a second-intermediate fabrication stage. During this stage, nanosheet patterning and formation of FET stacks 110a and 110b are carried out. Each of FET stacks 110a and 110b contain a respective FET device. However, this is merely illustrative and it is contemplated that any number of FET stacks can be formed and that FET stacks 110a and 110b can contain any number of FET devices. The FET stacks 110a and 110b may comprise nFET devices or pFET devices or combinations thereof. In an illustrative embodiment, FET stack 110a comprises an nFET device and FET stack 110b comprises a pFET device.

The FET stacks 110a and 110b may be formed by patterning hardmask layer 108 over the semiconductor structure 100, followed by etching exposed portions of the nanosheet channel layers 106 and sacrificial layers 104, and through a portion of the substrate 102.

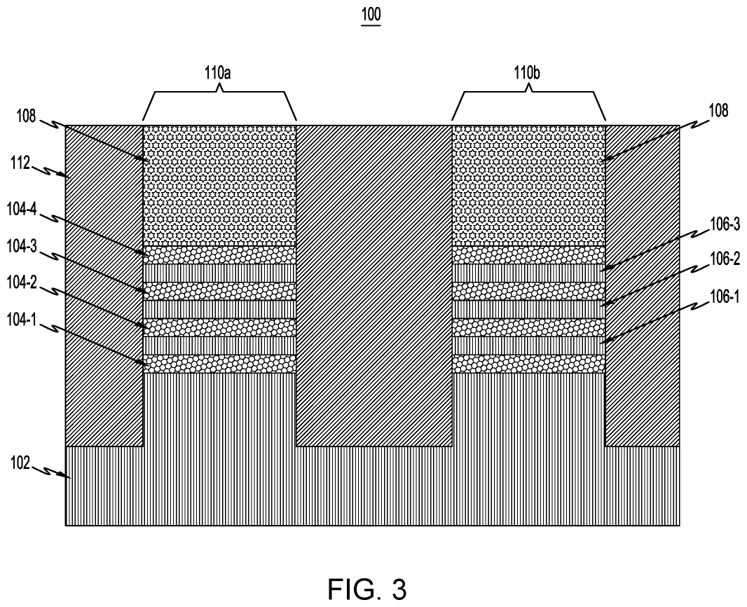

FIG. 3 shows semiconductor structure 100 at a third-intermediate fabrication stage. During this stage, shallow trench isolation (STI) regions 112 are formed on substrate 102 and on FET stacks 110a and 110b using any conventional deposition technique such as PVD, ALD, CVD and/or plating. The STI regions 112 may be formed of a dielectric material such as silicon dioxide (SiO₂), silicon oxycarbide (SiOC), silicon oxynitride (SiON), etc. After STI regions 112 are formed, a planarization process such as a CMP process can be carried out.

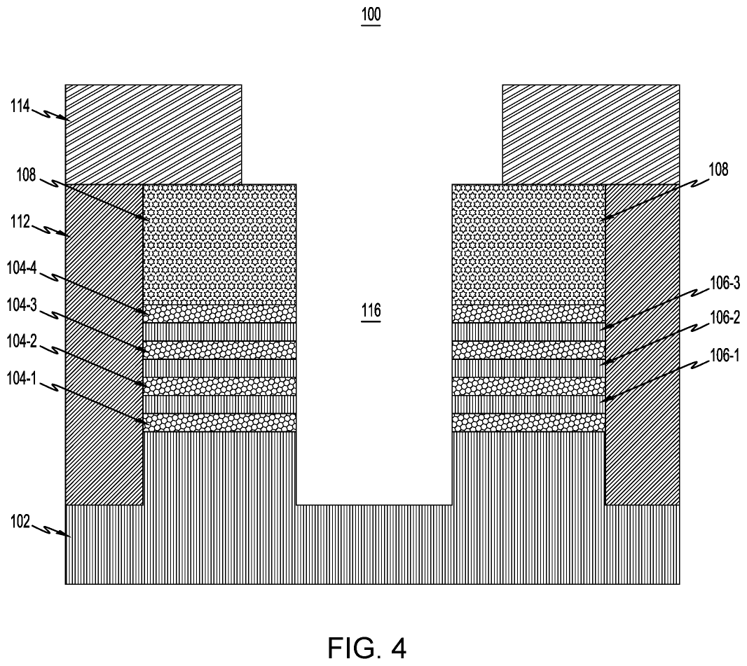

FIG. 4 shows semiconductor structure 100 at a fourth-intermediate fabrication stage. During this stage, the STI region of STI regions 112 between FET stacks 110a and 110b is selectively removed to form opening 116. In illustrative embodiments, a mask layer 114 (such as an organic planarization layer (OPL) can be deposited on at least a portion of hardmask layer 108 and on designated ones of STI regions 112 to expose the STI region of STI regions 112 between FET stacks 110a and 110b. Mask layer 114 can be deposited using any conventional deposition technique such as PVD, ALD, CVD and/or plating. Next, the STI region of STI regions 112 between FET stacks 110a and 110b is selectively removed using any conventional etching process such as reactive ion etching (RIE).

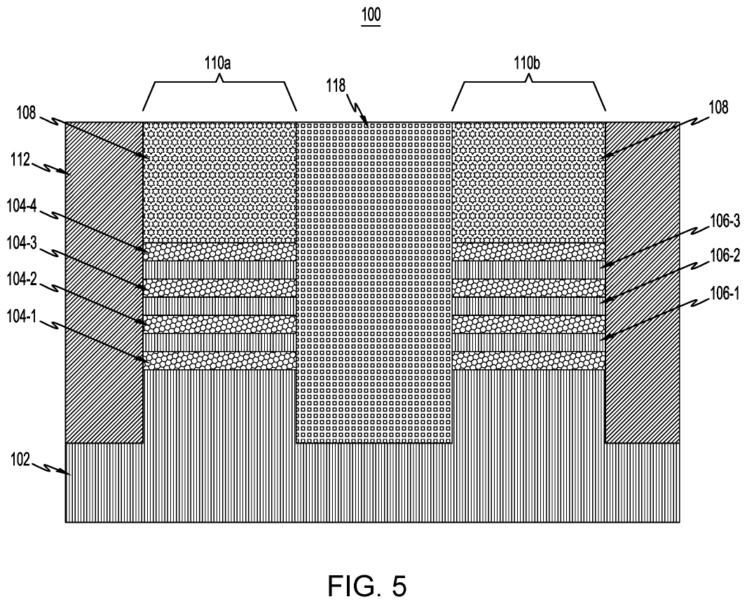

FIG. 5 shows semiconductor structure 100 at a fifth-intermediate fabrication stage. During this stage, mask layer 114 is removed by any suitable etching process such as a wet or dry etch. Next, a dielectric layer 118 is deposited in opening 116 between FET stacks 110a and 110b using conventional deposition techniques such as PVD, ALD and CVD. The dielectric layer 118 is a dielectric material having a first polarity of fixed charges. In an illustrative embodiment, in forming a dielectric layer 118 with positive charges, a dielectric material such as, for example, SiN is used. In another illustrative embodiment, in forming a dielectric layer 118 with negative charges, a dielectric material such as, for example, aluminum oxide (Al₂O₃), TiO₂, HfO₂, ZrO₂ or any other dielectric material having an oxygen vacancy, is used. In the instant case, illustrative dielectric layer 118 is a dielectric material having positive charges.

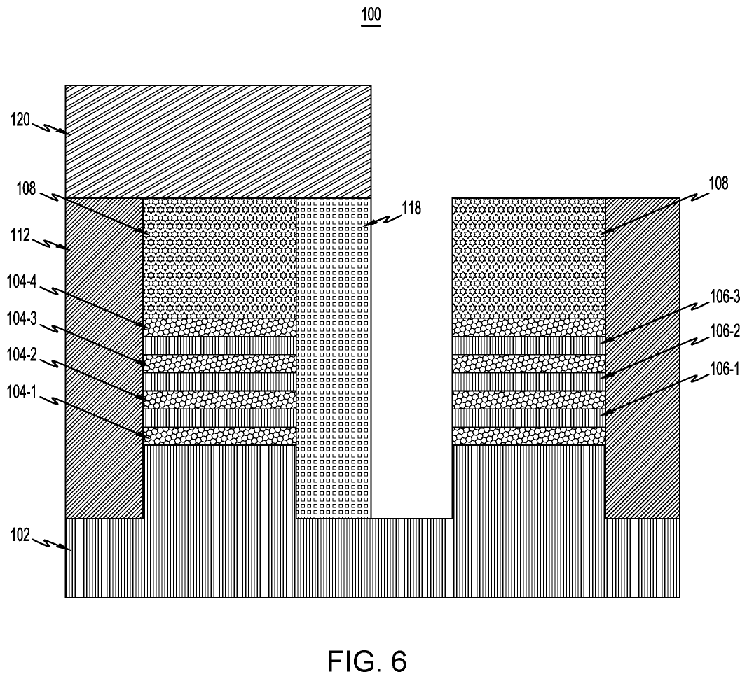

FIG. 6 shows semiconductor structure 100 at a sixth-intermediate fabrication stage. During this stage, a mask layer 120 is deposited on STI regions 112, hardmask layer 108 and a portion of dielectric layer 118 to be protected from being removed in subsequent etching process. In illustrative embodiments, the portion of dielectric layer 118 to be protected can vary widely. In one non-limiting illustrative embodiment, the portion of dielectric layer 118 to be protected can be equal to half the width of dielectric layer 118. Mask layer 120 can be formed by a similar process and of similar material as mask layer 114. The exposed portion of dielectric layer 118 can then be removed using any suitable selective etching process such as RIE.

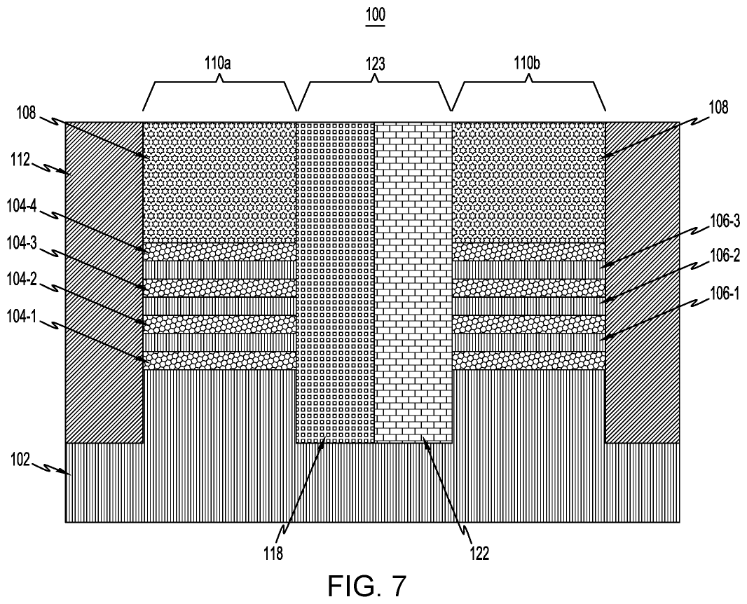

FIG. 7 shows semiconductor structure 100 at a seventh-intermediate fabrication stage. During this stage, mask layer 120 is removed by any suitable etching process such as a wet or dry etch. Next, a dielectric layer 122 is deposited in the opening between dielectric layer 118 and FET stack 110b to form dielectric pillar structure 123 between FET stacks 110a and 110b. The dielectric layer 122 is deposited in the opening between dielectric layer 118 and FET stack 110b using conventional deposition techniques such as PVD, ALD and CVD, followed by a planarization process such as CMP. The dielectric layer 122 is a dielectric material having fixed charges that has a polarity opposite of the charges of dielectric layer 118. In an illustrative embodiment, in forming a dielectric layer 118 with positive charges, the dielectric layer 122 will be a dielectric material with negative charges. In the instant case, illustrative dielectric layer 122 is a dielectric material having negative charges.

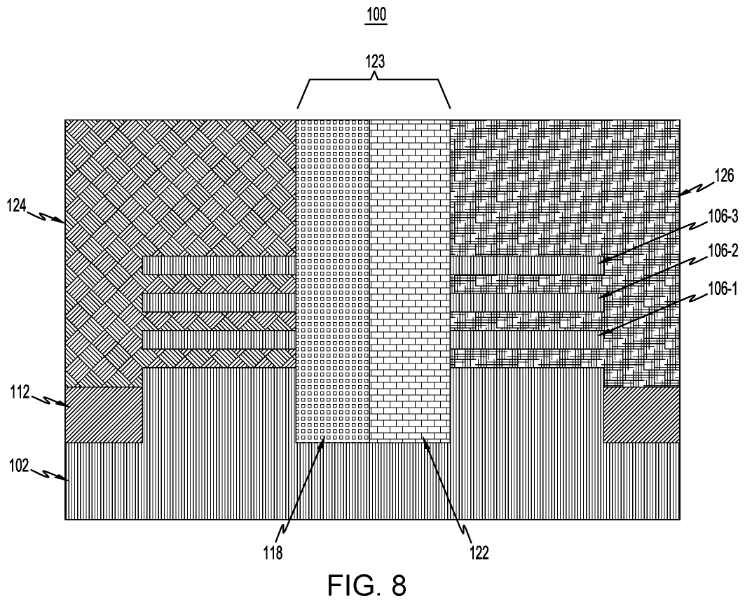

FIG. 8 shows semiconductor structure 100 at an eighth-intermediate fabrication stage. During this stage, various known processing steps not detailed in the present context are carried out to form a semiconductor structure that includes a first gate structure 124 and a second gate structure 126 on opposite sides of dielectric pillar structure 123, following the removal of hardmask layer 108 and sacrificial layers 104, and recessing of STI regions 112. First gate structure 124 and second gate structure 126 as depicted herein are intended to be representative in nature of any type of gate structure that may be employed in manufacturing integrated circuit products using so-called gate-last (replacement gate) manufacturing techniques. In particular, first gate structure 124 and a second gate structure 126 are formed on recessed STI regions 112 and around each of nanosheet channel layers 106 of FET stacks 110a and 110b employing, for example, ALD, CVD, RFCVD, plasma enhanced CVD (PECVD), physical vapor deposition (PVD), or molecular layer deposition (MLD). The first gate structure 124 and second gate structure 126 are then patterned to remove unwanted gate stack materials using conventional lithography and RIE techniques.

The first gate structure 124 and second gate structure 126 may comprise, for example, a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg).

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

In non-limiting illustrative embodiments, first gate structure 124 can be a pFET type gate structure and second gate structure 126 can be an nFET type gate structure. Accordingly, the semiconductor structure 100 of the illustrative embodiment can advantageously form a complementary metal oxide semiconductor (CMOS) cell having a n-type field-effect transistor (NFET) region and a p-type field-effect transistor (P-FET) region together with the dielectric pillar structure 123 including at least dielectric layer 118 and dielectric layer 122.

Referring now to FIGS. 9-14 illustrating an alternative non-limiting illustrative embodiment starting from FIG. 4, FIG. 9 illustrates semiconductor structure 200 at a first-intermediate fabrication stage. During this stage, mask layer 114 is removed by any suitable etching process such as a wet or dry etch. Next, a dielectric layer 128 is deposited on the exterior surfaces in opening 116 and over hardmask layer 108 and STI regions 112 using conventional deposition techniques such as PVD, ALD and CVD. The dielectric layer 128 can be of a dielectric material having a first polarity of fixed charges. In an illustrative embodiment, in forming a dielectric layer 128 with positive charges, a dielectric material can be any of the dielectric material having positive charges discussed above. In another illustrative embodiment, in forming a dielectric layer 128 with negative charges, a dielectric material can be any of the dielectric material having negative charges discussed above. In the instant case, illustrative dielectric layer 128 is a dielectric material having positive charges.

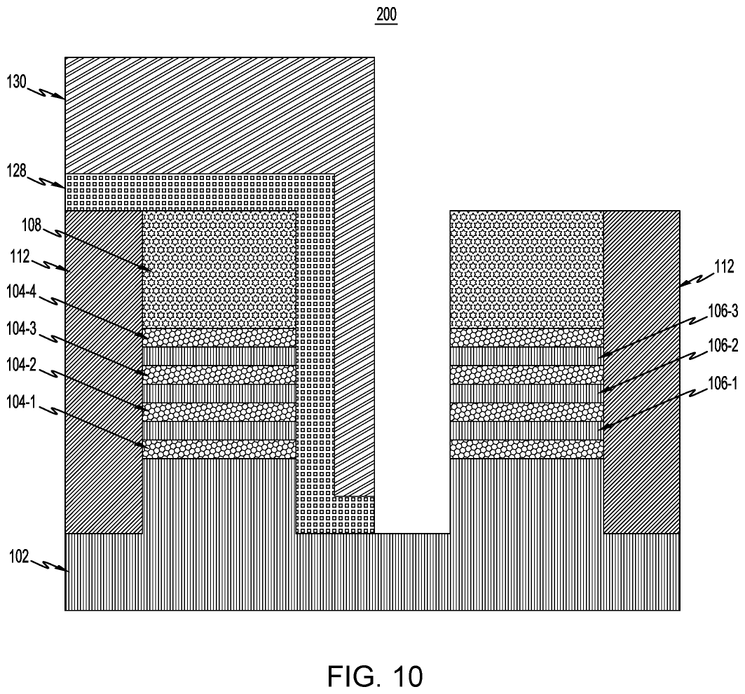

FIG. 10 shows semiconductor structure 200 at a second-intermediate fabrication stage. During this stage, a mask layer 130 is deposited on a portion of dielectric layer 128 to be protected from being removed in subsequent etching process. In illustrative embodiments, the portion of dielectric layer 128 to be protected can vary widely. In one non-limiting illustrative embodiment, the portion of dielectric layer 128 to be protected can be equal to half the width of the width of opening 116 depicted in FIG. 4. Mask layer 130 can be formed by a similar process and of similar material as mask layer 114. The exposed portion of dielectric layer 128 can then be removed using any suitable selective etching process such as RIE.

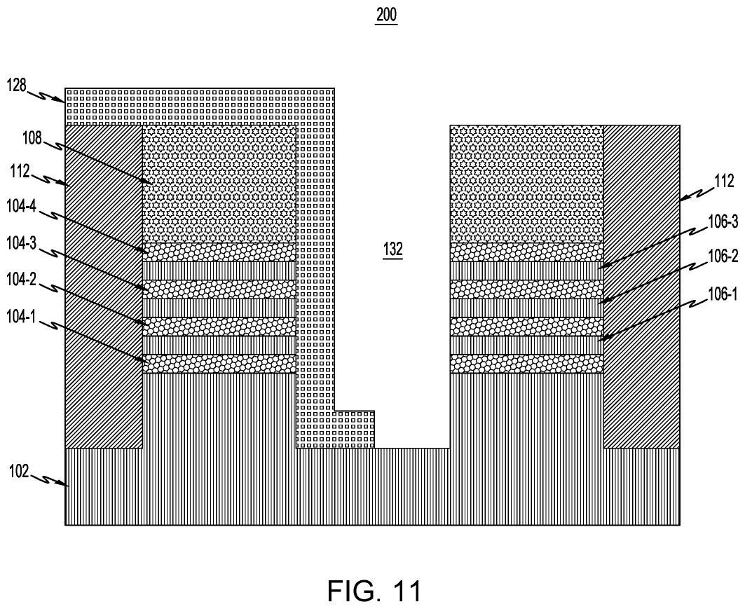

FIG. 11 shows semiconductor structure 200 at a third-intermediate fabrication stage. During this stage, mask layer 130 is removed by any suitable etching process such as a wet or dry etch to form opening 132.

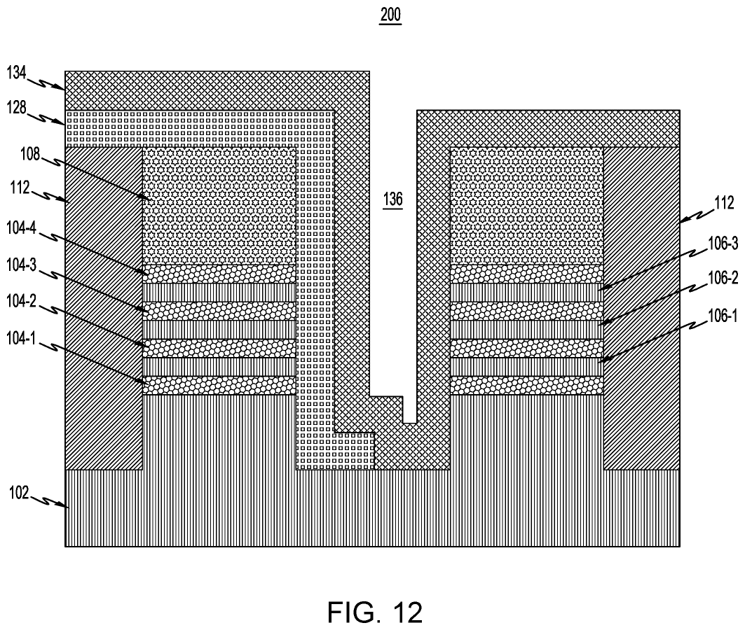

FIG. 12 shows semiconductor structure 200 at a fourth-intermediate fabrication stage. During this stage, a dielectric layer 134 is deposited on the top surface of dielectric layer 128 and on exterior surfaces of opening 132, hardmask layer 108 and STI regions 112 to form opening 136. The dielectric layer 134 is deposited using conventional deposition techniques such as PVD, ALD and CVD, followed by a planarization process such as CMP. The dielectric layer 134 is a dielectric material having fixed charges that has a polarity opposite of the charges of dielectric layer 128. In an illustrative embodiment, in forming a dielectric layer 134 with negative charges, a dielectric material can be any of the dielectric material having negative charges discussed above. In an illustrative embodiment, in forming a dielectric layer 134 with positive charges, a dielectric material can be any of the dielectric material having positive charges discussed above. In the instant case, illustrative dielectric layer 134 is a dielectric material having negative charges.

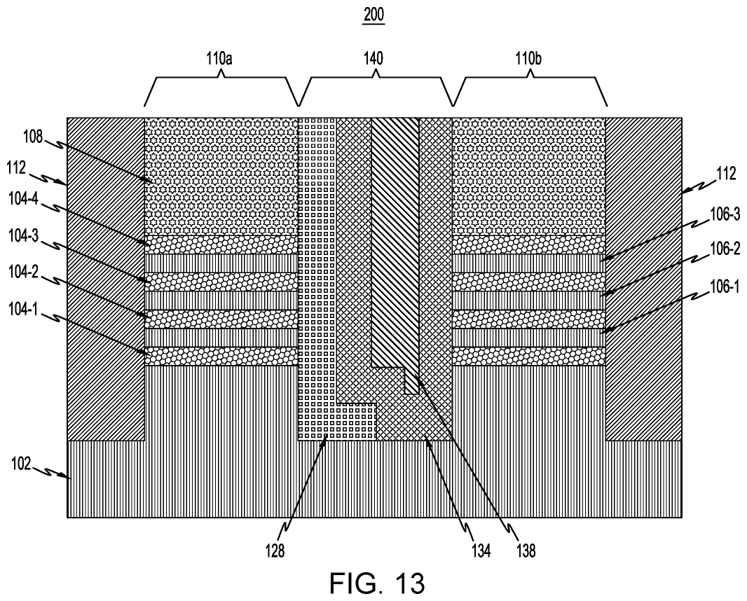

FIG. 13 shows semiconductor structure 200 at a fifth-intermediate fabrication stage. During this stage, an interlayer dielectric (ILD) layer 138 is deposited in opening 136 and between dielectric layers 128 and 134 to form dielectric pillar structure 140 using conventional deposition techniques such as PVD, ALD and CVD, followed by a planarization process such as CMP. ILD layer 138 may be formed of any suitable material such as, for example, SiOCN SiO₂, SiOC, SiON, etc.

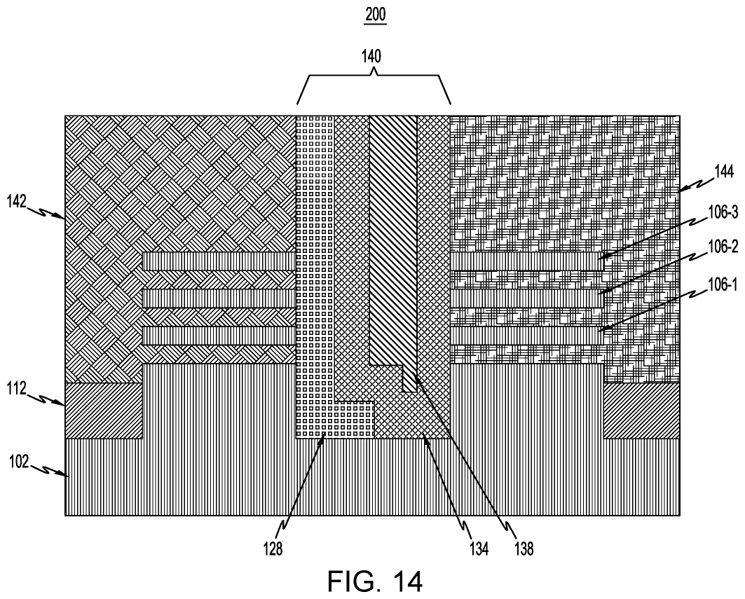

FIG. 14 shows semiconductor structure 200 at a sixth-intermediate fabrication stage. During this stage, various known processing steps not detailed in the present context are carried out to form a semiconductor structure 200 that includes a first gate structure 142 and a second gate structure 144 on opposite sides of dielectric pillar structure 140, following the removal of hardmask layer 108 and sacrificial layers 104, and recessing of STI regions 112. First gate structure 142 and second gate structure 144 can be formed by similar processes and of similar material and structure as first gate structure 124 and second gate structure 126.

Referring now to FIGS. 15 and 16 illustrating another alternative non-limiting illustrative embodiment starting from FIG. 11, FIG. 15 illustrates semiconductor structure 300 at a first-intermediate fabrication stage. During this stage, a dielectric layer 146 is deposited on the top surface of dielectric layer 128 and on exterior surfaces of opening 132 to form dielectric pillar structure 148. The dielectric layer 146 is deposited using conventional deposition techniques such as PVD, ALD and CVD, followed by a planarization process such as CMP. The dielectric layer 146 is a dielectric material having fixed charges that has a polarity opposite of the charges of dielectric layer 128. In an illustrative embodiment, in forming a dielectric layer 146 with negative charges, a dielectric material can be any of the dielectric materials having negative charges discussed above. In an illustrative embodiment, in forming a dielectric layer 146 with positive charges, a dielectric material can be any of the dielectric materials having positive charges discussed above. In the instant case, illustrative dielectric layer 146 is a dielectric material having negative charges.

FIG. 16 shows semiconductor structure 300 at a sixth-intermediate fabrication stage. During this stage, various known processing steps not detailed in the present context are carried out to form a semiconductor structure that includes a first gate structure 150 and a second gate structure 152 on opposite sides of dielectric pillar structure 148, following the removal of hardmask layer 108 and sacrificial layers 104, and recessing of STI regions 112. First gate structure 150 and second gate structure 152 can be formed by similar processes and of similar material and structure as first gate structure 124 and second gate structure 126.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising
a first transistor device;
a second transistor device; and
a dielectric pillar structure disposed between the first transistor device and the second transistor device, wherein the dielectric pillar structure comprises a first dielectric pillar adjacent the first transistor device and a second dielectric pillar adjacent the second transistor device.

2. The semiconductor structure of claim 1, wherein the first dielectric pillar comprises a first dielectric material having a first charge and the second dielectric pillar comprises a second dielectric material having a second charge opposite the first charge.

3. The semiconductor structure of claim 2, wherein the first dielectric material has a positive charge and the second dielectric material has a negative charge.

4. The semiconductor structure of claim 1, wherein the first transistor device is an NFET device, and the second transistor device is a PFET device.

5. The semiconductor structure of claim 1, wherein the first transistor device comprises a first nanosheet field-effect transistor device and the second transistor device comprises a second nanosheet field-effect transistor device.

6. The semiconductor structure of claim 5, wherein the first nanosheet field-effect transistor device further comprises a first gate structure and the second nanosheet field-effect transistor device further comprises a second gate structure.

7. The semiconductor structure of claim 6, wherein the first nanosheet field-effect transistor device and the second nanosheet field-effect transistor device provide a complementary field-effect transistor structure.

8. A semiconductor structure, comprising:
a first transistor device disposed on a substrate;
a second transistor device disposed on the substrate and adjacent the first transistor device; and
a dielectric pillar structure disposed between the first transistor device and the second transistor device, wherein the dielectric pillar structure comprises a first dielectric pillar disposed on the first transistor device and on a portion of the substrate, a second dielectric pillar disposed on the second transistor device and on sidewalls and a bottom portion of the first dielectric pillar and an interlayer dielectric layer disposed within the second dielectric pillar.

9. The semiconductor structure of claim 8, wherein the first dielectric pillar comprises a first dielectric material having a first charge and the second dielectric pillar comprises a second dielectric material having a second charge opposite the first charge.

10. The semiconductor structure of claim 9, wherein the first dielectric material has a positive charge and the second dielectric material has a negative charge.

11. The semiconductor structure of claim 10, wherein the first dielectric material comprises SiN, the second dielectric material comprises aluminum oxide (Al₂O₃) and the interlayer dielectric layer comprises SiOCN

12. The semiconductor structure of claim 8, wherein the first transistor device comprises a first nanosheet field-effect transistor device and the second transistor device comprises a second nanosheet field-effect transistor device.

13. The semiconductor structure of claim 12, wherein the first nanosheet field-effect transistor device further comprises a first gate structure and the second nanosheet field-effect transistor device further comprises a second gate structure.

14. The semiconductor structure of claim 9, wherein the first transistor device is an NFET device, and the second transistor device is a PFET device.

15. An integrated circuit, comprising:
one or more semiconductor structures, wherein at least one of the one or more semiconductor structures comprises:
a first transistor device;
a second transistor device; and
a dielectric pillar structure disposed between the first transistor device and the second transistor device, wherein the dielectric pillar structure comprises a first dielectric pillar adjacent the first transistor device and a second dielectric pillar adjacent the second transistor device.

16. The integrated circuit of claim 15, wherein the first dielectric pillar comprises a first dielectric material having a first charge and the second dielectric pillar comprises a second dielectric material having a second charge opposite the first charge.

17. The integrated circuit of claim 16, wherein the first transistor device is an NFET device, and the second transistor device is a PFET device.

18. The integrated circuit of claim 15, wherein the first transistor device comprises a first nanosheet field-effect transistor device and the second transistor device comprises a second nanosheet field-effect transistor device.

19. The integrated circuit of claim 18, wherein the first nanosheet field-effect transistor device further comprises a first gate structure and the second nanosheet field-effect transistor device further comprises a second gate structure.

20. The integrated circuit of claim 19, wherein the first nanosheet field-effect transistor device and the second nanosheet field-effect transistor device provide a complementary field-effect transistor structure.
